(19) United States
(12) Patent Application Publication
(10) Pub. No.: US 2008/0041527 A1
(43) Pub. Date: Feb. 21, 2008

(54) Antenna of plasma processing apparatus

(75) Inventors: Seung-Ho Lee, Suwon-si (KR); Jeong-Beom Ryeo, Seoul (KR)

Correspondence Address: HARNESS, DICKEY & PIERCE, P.L.C., P.O. BOX 8910, RESTON, VA, 20195, US

(73) Assignee: ICD CO., LTD.

(21) Appl. No.: 11/523,055

(22) Filed: Sep. 19, 2006

(30) Foreign Application Priority Data
Aug. 17, 2006 (KR) 10-2006-0077838

(51) Int. Cl. C23F 1/00; C23C 16/00

(52) U.S. Cl. 156/345.48; 118/723 I

(57) ABSTRACT

An antenna of a plasma processing apparatus includes first and second wiring groups that respectively are electrically coupled to different RF power source. The first wiring group is formed on an internal region and an intermediate region, and the first wiring group transfers a power of a first RF power source from the intermediate region to the internal region. The second wiring group is formed on the intermediate region and an outer region. The second wiring group receives a power of a second RF power source from the intermediate region, or alternatively from the outer region. The frequency of the second RF power applied to the second wiring group is lower than the frequency of the first RF power applied to the first wiring group, thereby reducing the plasma loss at the outer region.

### CLAIM FOR PRIORITY

This application claims priority to Korean Patent Application No. 2006-77838 filed on Aug. 17, 2006 in the Korean Intellectual Property Office (KIPO), the entire contents of which are hereby incorporated by reference.

### BACKGROUND

1. Field of the Invention

Example embodiments of the present invention relates to the field of an antenna of inductively coupled plasma processor, and more specifically to an antenna of inductively coupled plasma processor that employs a plurality of RF power sources.

2. Description of the Related Art

A plasma may be defined as a fourth status of material, an ionized gas, or a quasi-neutral gas, which has collective behavior characteristics, comprised of neutral particles and particles with electrical polarity. Especially, a plasma process represents a process that uses the plasma characterized with the collective behavior and the quasi-material. The plasma process may be applied to deposition, ion-nitriding, and ashing.

Recently, the plasma has been used in semiconductor manufacturing process and display device manufacturing process. In the semiconductor manufacturing process, the plasma is applied to an etching process and a deposition process on a semiconductor substrate, and an ashing process for photoresist. In the display device manufacturing process, the plasma is applied to an etching process for amorphous silicon or poly silicon, a patterning process for metallization, and a process of forming color filters on a transparent substrate.

Especially, in the display device manufacturing process, it is required a uniform plasma flux density (or plasma density) on the overall surface of the transparent substrate (workpiece) because the transparent substrate becomes larger. An inductively coupled plasma processor using an RF (Radio Frequency) discharge is mainly used so as to provide the uniform plasma flux density on the overall surface of the transparent substrate.

The inductively coupled plasma processor applies an RF power voltage to the plasma via a coil disposed in a space on the transparent substrate, and electric field is formed in a direction parallel to the transparent substrate in response to magnetic flux generated by the RF power voltage. Hereinafter, the coil through which the RF power voltage is applied is referred to as an antenna. The configuration of the antenna is important so as to provide uniform plasma flux density on the workpiece. The configuration of the antenna changes the magnetic flux around the antenna, and the changed magnetic flux changes the electric field applied to the plasma. Thus, various techniques for modifying the configuration of the antenna have been proposed so as to provide uniform plasma flux density on the workpiece.

U.S. Pat. No. 6,268,700 (entitled “Vacuum plasma processor having coil with intermediate portion coupling lower magnetic flux density to plasma than center and peripheral portions of the coil” and allowed to the inventor Holland) discloses an configuration of an antenna for providing uniform plasma flux density on the workpiece. According to the U.S. Pat. No. 6,268,700, the antenna includes one electrically connected wiring, an RF power source is electrically coupled to an antenna center point, and a ground of the antenna is coupled to corner portion of the rectangular spiral antenna. In the U.S. Pat. No. 6,268,700, the interval between the wirings of the antenna at an internal region is narrow, and the interval between the wirings of the antenna at an intermediate region is wide, and the interval between the wirings of the antenna at an outer region is narrow. Especially, parallelly coupled wirings are arranged at corner of the outer region so as to increase the magnetic flux density at the corner of the outer region.

However, the antenna disclosed in the U.S. Pat. No. 6,268,700 is not proper for a large substrate. A center portion of the substrate has a lower etching rate due to the impedance formed by a dielectric window disposed under the antenna and the impedance formed by a plasma sheath. In addition, in case the parallelly coupled wirings are arranged at the corner of the outer region so as to increase the magnetic flux density of the corner of the outer region, the magnetic flux density at the corner of the outer region may decrease because a magnetic flux has characteristics where the magnetic flux increases in proportional to the quantity of current. As shown in FIG. 5 of the U.S. Pat. No. 6,268,700, the etching rate at the center and the peripheral corner is remarkably decreased.

Therefore, it is required an antenna of which configuration can provide uniform plasma flux density on the large substrate.

### SUMMARY

Accordingly, the present invention is provided to substantially obviate one or more problems due to limitations and disadvantages of the related art.

Example embodiments of the present invention provide an antenna, which may provide uniform plasma flux density on the large substrate, of a plasma processing apparatus

In some example embodiments, an antenna of a plasma processing apparatus includes a first wiring group and a second wiring group. The first wiring group is formed on an internal region and an intermediate region, and transfers a power of a first RF (radio frequency) power source from the intermediate region to the internal region. The second wiring group is formed on the intermediate region and an outer region, and transfers a power of a second RF (radio frequency) power source from the intermediate region to the outer region.

In other example embodiments, an antenna of a plasma processing apparatus includes a first wiring group and a second wiring group. The first wiring group is formed on an internal region and an intermediate region, and transfers a power of a first RF (radio frequency) power source from the intermediate region to the internal region. The second wiring group is formed on the intermediate region and an outer region, and transfers a power of a second RF (radio frequency) power source from the outer region to the intermediate region.

In still other example embodiments, an antenna of a plasma processing apparatus includes a first wiring group and a second wiring group. The first wiring group is formed from on an internal region and an intermediate region, and the first wiring group receives a power of a first RF (radio frequency) power source. The second wiring group is formed on the intermediate region and an outer region, and receives a power of a second RF (radio frequency) power source different from the first RF power source.

### BRIEF DESCRIPTION OF THE DRAWINGS

Example embodiments of the present invention will become more apparent by describing in detail example embodiments of the present invention with reference to the accompanying drawings, in which:

FIG. 1 is a plane view showing the configuration of an antenna according to an exemplary embodiment of the present invention;

FIG. 2 is a plane view showing the configuration of an antenna according to another exemplary embodiment of the present invention;

FIG. 3 is a plane view showing the configuration of an antenna according to still another exemplary embodiment of the present invention;

FIG. 4 is a graph showing plasma density distribution under a conventional antenna;

FIG. 5 is a graph showing a plasma density distribution under an antenna according to an exemplary embodiment of the present invention;

FIG. 6 shows etching rate under a conventional antenna; and

FIG. 7 shows etching rate under an antenna according to an exemplary embodiment of the present invention.

### DESCRIPTION OF EXAMPLE EMBODIMENTS OF THE PRESENT INVENTION

Example embodiments of the present invention are disclosed herein. However, specific structural and functional details disclosed herein are merely representative for purposes of describing example embodiments of the present invention, however, example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

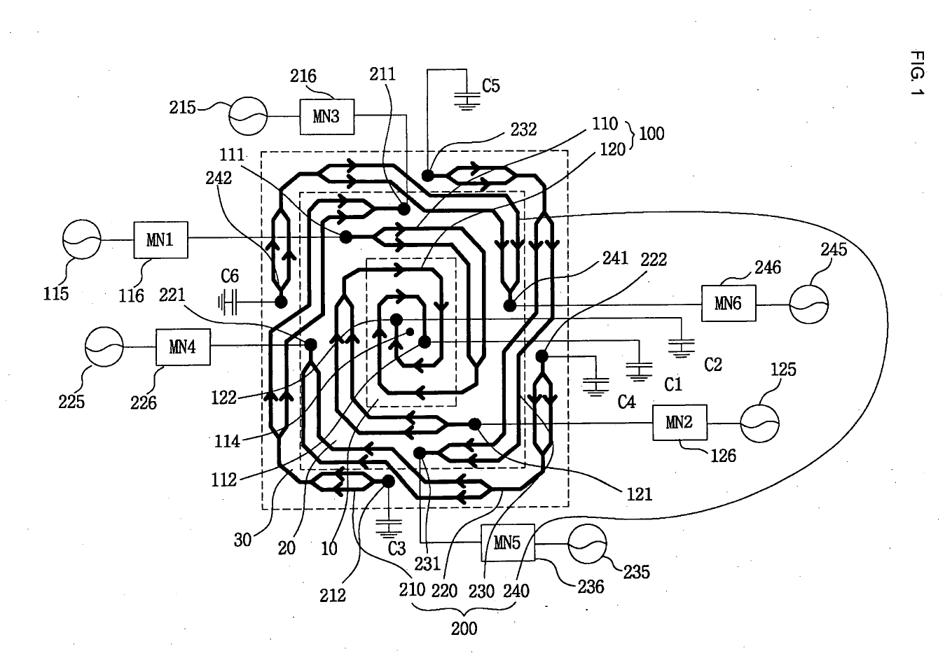

FIG. 1 is a plane view showing the configuration of an antenna according to an exemplary embodiment of the present invention.

Referring to FIG. 1, the antenna according to an exemplary embodiment of the present invention includes a first wiring group 100 and a second wiring group 200.

The first wiring group 100 is formed from an intermediate region 10 into an internal region 20, and the second wiring group 200 is formed from the intermediate region 20 into an outer region 30. The first RF (radio frequency) power supplied to the first wiring group 100 is transferred from the intermediate region 20 to the internal region 10 via the first wiring group 100. In addition, the second RF (radio frequency) power supplied to the second wiring group 200 is transferred from the intermediate region 20 to the outer region 30 via the second wiring group 200.

The first wiring group 100 includes a first wiring 110 and a second wiring 120. The first wiring 110 is coupled, at the intermediate region 20, to the first RF power source 115, and is formed from the intermediate region 20 into the internal region 10 so that the first wiring 110 may have a square spiral configuration. In addition, the first wiring 110 has at least two parallelly coupled conductive wires in the intermediate region 20. Namely, a first input terminal 111 disposed in the intermediate region 20 is coupled to the first RF power source 115 through a first matching network 116, and a first output terminal 112 disposed in the internal region 10 is coupled to a ground through a first capacitor C1. The first wiring 110 in the internal region 10 has one conductive wire having a spiral configuration.

Hereinafter, the input terminal of each of the wirings represents a terminal nearest to the RF power source, and the output terminal of each of the wirings represents a terminal farthest from the RF power source.

The first and the second wiring 110 and 120 are arranged substantially diagonally symmetrically with respect to an antenna center point 114. A second input terminal 121 of the second wiring 120 coupled to a second RF power source 125 and the first input terminal 111 of the first wiring 110 are disposed substantially diagonally symmetrically with respect to the antenna center point 114. In addition, a second output terminal 122 of the second wiring 120 and a first output terminal 112 of the first wiring 110 are disposed substantially diagonally symmetrically with respect to the antenna center point 114. The second output terminal 122 of the second wiring 120 is coupled to the ground through the second capacitor C2.

The first wiring 110 and the second wiring 120 are disposed substantially diagonally symmetrically with respect to the antenna center point 114, and have square spiral configuration as shown in FIG. 1. A predetermined interval between the first wiring 110 and the second wiring 120 is formed. The power of the first RF power source 115 transmitted through the first wiring 110 and the power of the second RF power source 125 transmitted through the second wiring 120 generate magnetic flux in a direction substantially perpendicular to a plane to which the wirings 110 and 120 belong. The generated magnetic flux in the direction substantially perpendicular to the plane induces electric field in parallel to the plane to which the wirings 110 and 120 belong.

In addition, the amplitude, phase and frequency of the first RF power source 115 may be the same as those of the second RF power source 125. Thus, the first RF power source 115 and the second RF power source 125 may be replaced by one RF power source, and the first matching network 116 and the second matching network 126 may be replaced by one matching network.

An amplitude of an RF power voltage applied to a wiring increases and an amplitude of an RF power current applied to a wiring increases according as a distance from a RF power source increases. Since the magnetic flux density generated by a wiring increases substantially in proportion to the amount of the current flowing through the wiring, a low magnetic flux density is formed at region near to the RF power source, and a high magnetic flux density is formed at region far from the RF power source. Therefore, a relatively low magnetic flux density is formed at the intermediate region 20 into which the power of the RF power sources 115 and 125 are directly applied, and a relatively high magnetic flux density is formed at the internal region 10 relatively far from the RF power sources 115 and 125.

The second wiring group 200 formed on the intermediate region 20 and the outer region 30 includes a third wiring 210, a fourth wiring 220, a fifth wiring 230, and a sixth wiring 240. The third, fourth, fifth and sixth input terminals 211, 221, 231 and 241, disposed at the intermediate region 20, of the respective third, fourth, fifth and sixth wiring 210, 220, 230 and 240 are coupled to the respective RF power sources 215, 225, 235 and 245. The third, fourth, fifth and sixth output terminals 212, 222, 232 and 242, disposed at the outer region 30, of the respective third, fourth, fifth and sixth wiring 210, 220, 230 and 240 are coupled to the ground.

The third input terminal 211 of the third wiring 210 is electrically coupled to the third RF power source 215 through the third matching network 216. The third wiring 210 has at least two parallelly coupled conductive wires at the intermediate region 20 and at the outer region 30. Especially, the third wiring 210 may have a conductive wire at a corner of the outer region 30, and may have at least two parallelly coupled conductive wires at the edge of the outer region 30.

Due to the effect of the magnetic flux generated at the internal region 10 and the outer region 30, the electric flux density induced at the intermediate region 20 is higher than the electric flux density induced at the internal region 10 and the outer region 30. Thus, so as to remove effect of the magnetic flux generated at the internal region 10 and the outer region 30, a RF power current having a low amplitude is supplied to the intermediate region 20, thus a relatively low magnetic flux density is formed at the intermediate region 20, and a RF power current having a high amplitude is supplied to the outer region 30 and to the corner of the outer region 30, thus a relatively high magnetic flux density is formed at the outer region 30. Especially, a conductive wire instead of parallelly coupled wires is disposed at a corner of the outer region 30 so as to increase the magnetic field induced by the current flowing through a wire.

In addition, the third, fourth, fifth and sixth input terminals 211, 221, 231 and 241 disposed at the edges of the intermediate region 20 are coupled to the RF power sources 215, 225, 235 and 245, respectively, through the matching networks 216, 226, 236 and 246, respectively. In case an input terminal is disposed at a corner of the intermediate region 20 and an RF power is coupled to the input terminal disposed at the corner of the intermediate region 20, a very low magnetic flux density is induced at the corner of the intermediate region 20, and thus it is difficult to provide uniform electric field on the substrate.

The fourth input terminal 221 of the fourth wiring 220 is electrically coupled to the fourth RF power source 225 through the fourth matching network 226. The fourth wiring 220 has at least two parallelly coupled conductive wires at the intermediate region 20 and at the outer region 30. Especially, the fourth wiring 220 may have a conductive wire at a corner of the outer region 30, and may have at least two parallelly coupled conductive wires at an edge of the outer region 30.

Above described configuration may be similarly applied to the fifth input terminal 231 and the fifth output terminal 232 of the fifth wiring 230. Namely, the fifth input terminal 231, which is disposed at an edge of the intermediate region 20, of the fifth wiring 230 is electrically coupled to the fifth RF power source 235 through the fifth matching network 236, and the fifth output terminal 232, which is disposed at an edge of the outer region 30, of the fifth wiring 230 is electrically coupled to the ground via the fifth capacitor C5.

In a similar way, the sixth input terminal 241 of the sixth wiring 240 is electrically coupled to the sixth RF power source 245 through the sixth matching network 246, and the sixth output terminal 242 of the sixth wiring 240 is electrically coupled to the ground via the sixth capacitor C6.

The third, fourth, fifth and sixth wirings 210, 220, 230 and 240 have the same shape. The fourth, fifth and sixth wirings 220, 230 and 240 are formed by rotating the third wiring 210 by about 90 degree, about 180 degree and about 270 degree with respect to an antenna center point, respectively. In addition, the RF power sources 215, 225, 235 and 245 that apply the RF power to the wirings 210, 220, 230 and 240 may have the same phase and the same frequency. Thus, the RF power sources 215, 225, 235 and 245 may be replaced by one RF power source, and the matching networks 216, 226, 236 and 246 may be replaced by one matching network.

The number of the wirings of the second wiring group 200 formed on the intermediate region 20 and the outer region 30 may vary depending upon the area of the plasma formed by the antenna and the area of the substrate (workpiece). For example, the number of the wirings of the second wiring group 200 may increase according as the area of the substrate increases.

Similarly, the number of the wirings of the first wiring group 100 formed on the intermediate region 20 and the internal region 10 may vary depending upon the area of the plasma formed by the antenna and the area of the substrate (workpiece). For example, the number of the wirings, which is formed on the intermediate region 20 and the internal region 10, of the first wiring group 100 may be one when the area of the substrate is narrow, and the number of the wirings, which which is formed on the intermediate region 20 and the internal region 10, of the first wiring group 100 may be two or more than two when the area of the substrate is large.

The length of the wiring through which the RF power is transmitted may vary depending upon the area of the substrate. When the wavelength of the RF power is λ, the limit length of the wiring through which the RF power is transmitted is λ/4. Thus, the number of the wirings may be increased compared with the number of the wirings shown in FIG. 1 when the area of the substrate is large.

In the example embodiment shown in FIG. 1, wirings are formed on the intermediate region 20 and the internal region 10, the wirings have at least two parallelly coupled conductive wires at the intermediate region 20, and the wirings have a conductive wire on the internal region 10. In addition, the RF power is supplied from the intermediate region 20 to the internal region 10 so as to prevent the decrease of the magnetic flux density at the internal region 10.

Similarly, another wirings are formed on the intermediate region 20 and the outer region 30, the another wirings have at least two parallelly coupled conductive wires at the intermediate region 20, and the another wirings have a conductive wire at a corner of the outer region 30 so as to prevent the decrease of the magnetic flux density at the outer region 30. The RF power is coupled to input terminals formed on the intermediate region 20, and is coupled to the ground through the output terminals 212, 222, 232 and 242 and the capacitors C1, C2, C3 and C4 formed around edges of the outer region 30.

Therefore, uniform electric field and uniform plasma flux density (or plasma density) may be formed on a large substrate based on above described configuration of the antenna.

In addition, the power of the first RF power source 115 and the power of the second RF power source 125 have substantially inverted phase with respect to the phase of the third, fourth, fifth and sixth RF power sources 215, 225, 235 and 245 coupled to the third, fourth, fifth and sixth wirings 210, 220, 230 and 240 formed on the intermediate region 20 and the outer region 30, so that the RF current flowing through the antenna may be represented as a phasor with a predetermined phase. Namely, the RF current flowing through the first and second wirings 110 and 120 formed on the intermediate region 20 and the internal region 10 has the same phase (or direction) as the phase of the RF current flowing through the third, fourth, fifth and sixth wirings 210, 220, 230 and 240 formed on the intermediate region 20 and the outer region 30. Thus, the power of the first RF power source 115 and the power of the second RF power source 125 have substantially a phase difference of π with respect to the phase of the third, fourth, fifth and sixth RF power sources 215, 225, 235 and 245.

In addition, a frequency of the RF power sources 115 and 125 that transmit the power from the intermediate region 20 to the internal region 10 may be higher than a frequency of the RF power sources 215, 225, 235 and 245 that transmit the power from the intermediate region 20 to the outer region 30.

Thus, the plasma loss at the outer region 30 may be reduced. A sidewall of a chamber in which the plasma is formed is electrically connected to ground, and the loss of ions and electrons occurs at the sidewall electrically connected to the ground. Electrons having relatively light weight arrives first at the surface of the sidewall connected to the ground, and recombines with the ions existing in the vicinity of the sidewall. The amount of the plasma loss at the sidewall is substantially in proportion to the frequency of the RF power applied to the antenna. Namely, the plasma loss at the sidewall is relatively small when the frequency of the RF power is low. Particularly, the plasma loss is related to variables such as the degree of ionization, the temperature of the plasma, the temperature of electrons, debye length or plasma sheath. Thus, the frequency of the RF power that is transferred from the intermediate region 20 into the outer region 30 is regulated to be relatively low so as to minimize the plasma loss at the outer region 30.

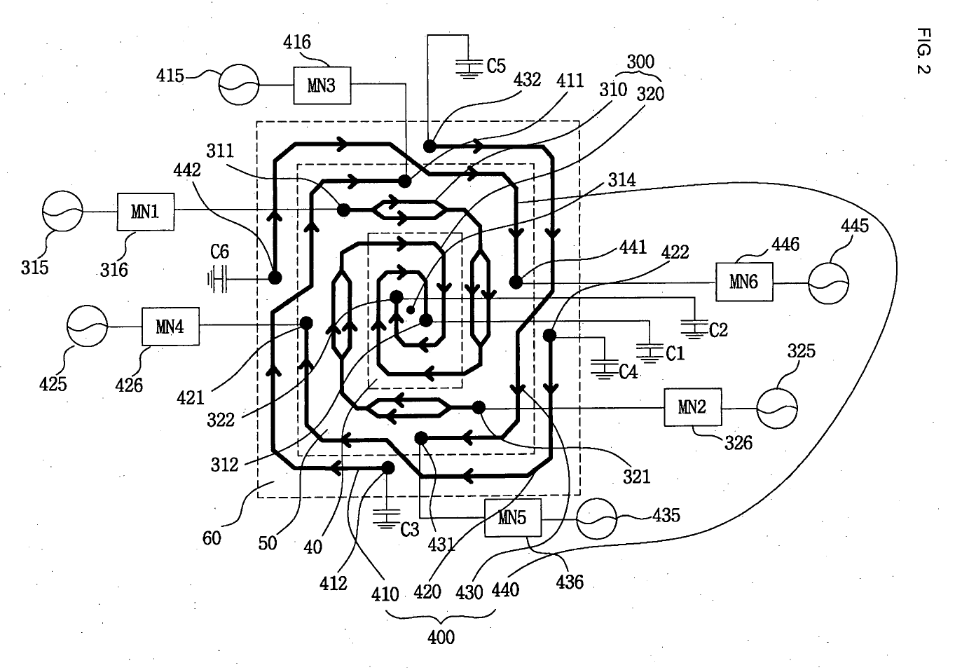

FIG. 2 is a plane view showing the configuration of an antenna according to another exemplary embodiment of the present invention.

Referring to FIG. 2, the antenna according to another exemplary embodiment of the present invention includes a first wiring group 300 and a second wiring group 400.

The first wiring group 300 is formed from an intermediate region 50 into an internal region 40. The first wiring group 300 receives the first RF (radio frequency) power at the intermediate region 50 to transmit the first RF power to the internal region 40.

The second wiring group 400 is formed from the intermediate region 50 into an outer region 60. The second wiring group 400 receives the second RF (radio frequency) power at the intermediate region 50 to transmit the second RF power to the outer region 60.

The first wiring group 300 includes a first wiring 310 and a second wiring 320.

The first wiring 310 and the second wiring 320 are arranged to have substantially a spiral configuration, and a predetermined interval between the first wiring 310 and the second wiring 320 is formed so that the first wiring 310 and the second wiring 320 dose not intersect each other. The first wiring 310 and the second wiring 320 may have substantially a square spiral configuration.

A first input terminal 311 is coupled to the first RF power source 315 through a first matching network 316, and a first output terminal 312 is coupled to a ground through a first capacitor C1. The first wiring 310 has at least two parallelly coupled conductive wires in the intermediate region 50. The first wiring 310 may have one conductive wire at corners of the intermediate region 50 and may have at least two parallelly coupled conductive wires at edges of the intermediate region 50 so at to prevent the decrease of the magnetic flux density.

The first wiring 310 may have one conductive wire in the internal region 40 so at to strengthen the induced electric field.

A second input terminal 321 of the second wiring 320 is coupled to the second RF power source 325 through a second matching network 326, and a second output terminal 322 is electrically coupled to a ground through a second capacitor C2.

The first and second wirings 310 and 320 receives, at the intermediate region 50, the RF power, and transfers the RF power to the internal region 40, thereby strengthening the electric flux density in the internal region 40 that has relatively low electric flux density. The first and second wirings 310 and 320 have parallelly coupled conductive wires in the intermediate region 50 and receives, at the intermediate region 50, the RF power, thereby weakening the electric flux density in the intermediate region 50 that has relatively high electric flux density.

Therefore, the electric flux density in the internal region 40 and the intermediate region 50 may be maintained to be uniform, and uniform plasma flux density may be obtained.

The second wiring group 400, which is formed on the intermediate region 50 and the outer region 60 as shown in FIG. 2, includes third, fourth, fifth and sixth wirings 410, 420, 430 and 440.

The powers of the RF power sources 415, 425, 435 and 445 are applied to the third, fourth, fifth and sixth wirings 410, 420, 430 and 440 in the same way as shown in FIG. 1, and the third, fourth, fifth and sixth wirings 410, 420, 430 and 440 are electrically coupled to the ground through the capacitors C3, C4, C5 and C6 in the same way as shown in FIG. 1. Thus, the third, fourth, fifth and sixth input terminals 411, 421, 431 and 441 which are disposed in the intermediate region 50, of the third, fourth, fifth and sixth wirings 410, 420, 430 and 440 are electrically coupled to the third, fourth, fifth and sixth RF power sources 415, 425, 435 and 445 through the third, fourth, fifth and sixth matching network 416, 426, 436 and 446, respectively, and the third, fourth, fifth and sixth output terminals 412, 422, 432 and 442, which are disposed in the outer region 60, of the third, fourth, fifth and sixth wiring 410, 420, 430 and 440 are electrically coupled to the ground via the capacitors C3, C4, C5 and C6, respectively. The third, fourth, fifth and sixth wirings 410, 420, 430 and 440 may respectively have one conducting wire.

In the example embodiment shown in FIG. 2, the antenna includes at least two wiring groups 300 and 400, and the RF power is transferred from the intermediate region 50 to the internal region 40 via the first wiring group 300. In addition, the RF power is transferred from the intermediate region 50 to the outer region 60 via the second wiring group 400. Therefore, uniform induced electric flux density may be formed throughout the overal regions (internal, intermediate and outer regions) of the antenna, and uniform plasma flux density may be obtained based on the uniform induced electric flux density.

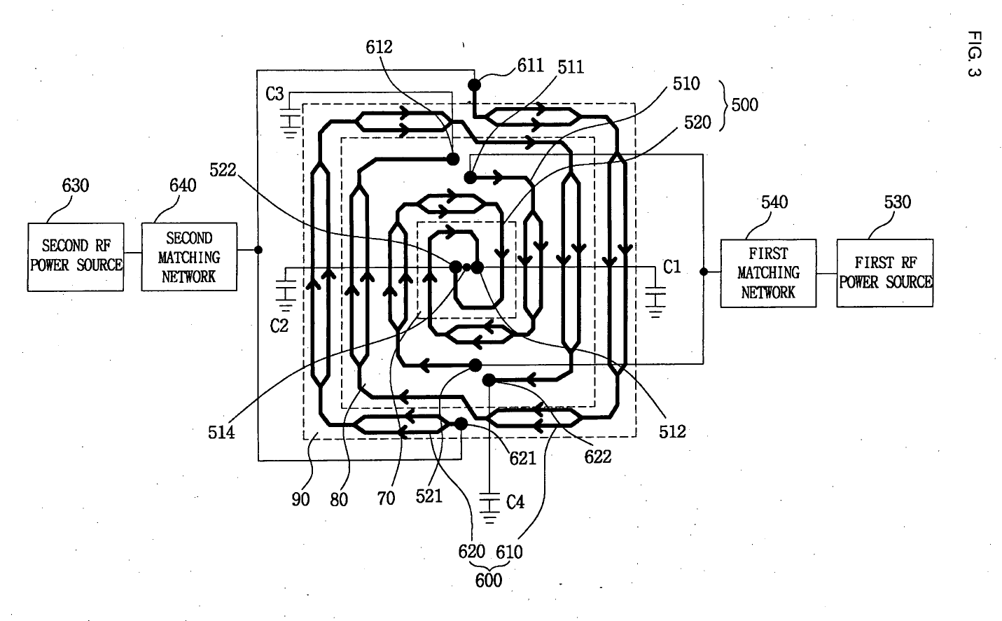

FIG. 3 is a plane view showing the configuration of an antenna according to still another exemplary embodiment of the present invention.

Referring to FIG. 3, the antenna includes a first wiring group 500 and a second wiring group 600.

The first wiring group 500 is formed on the intermediate region 80 and on the internal region 70. First and second input terminals 511 and 521, which are formed in the intermediate region 80, of the first wiring group 500 are coupled to a first RF power source 530 through a first matching network 540, and first and second output terminals 512 and 522, which are formed in the internal region 70, of the first wiring group 500 are coupled to a ground through first and second capacitors C1 and C2.

The first wiring group 500 includes a first wiring 510 and a second wiring 520.

The first wiring 510 includes the first input terminal 511 at an edge of the intermediate region 80 and the first output terminal 512 in the internal region 70. The first input terminal 511 is coupled to the first RF power source 530 through the first matching network 540, and the first output terminal 512 is coupled to a ground through the first capacitor C1. The first wiring 510 receives the RF power at the edge of the intermediate region 80, and transfers the RF power to the internal region 70. An amplitude of an RF current flowing through a transmission line increases according as a distance from a RF power source increases. Thus, since the internal region 70 is relatively far from the first RF power source 530, a strong electric field is induced in the internal region 70.

In addition, the first wiring 510 is formed from the intermediate region 80 into the internal region 70 so that the first wiring 510 may have a spiral configuration. The first wiring 510 has at least two parallelly coupled conductive wires in the intermediate region 80. The first wiring 510 may have one conductive wire at corners of the intermediate region 80 so that the RF current may not be divided (or branched) through parallelly coupled conductive wires at the corners of the intermediate region 80.

The second wiring 520 is formed by rotating the first wiring 510 by about 180 degree with respect to an antenna center point 514. Thus, the second input terminal 521 of the second wiring 520 and the first input terminal 511 of the first wiring 510 are arranged substantially diagonally symmetrically with respect to the antenna center point 514. The second output terminal 522 of the second wiring 520 and the first output terminal 512 of the first wiring 510 are arranged substantially diagonally symmetrically with respect to the antenna center point 514.

A second input terminal 521, which is disposed in the intermediate region 80, of the second wiring 520 is coupled to the first RF power source 530 through the first matching network 540, and a second output terminal 522, which is disposed in the internal region 70, of the second wiring 520 is coupled to a ground through a second capacitor C2. The effect of the second wiring 520 is substantially the same as that of the first wiring 510.

The second wiring group 600 is formed on the intermediate region 80 and on the outer region 90. The second wiring group 600 includes a third wiring 610 and a fourth wiring 620.

The third wiring 610 is formed from an edge of the outer region 90 into an edge of the intermediate region 80. Third input terminal 611 of the third wiring 610 is disposed at an edge of the outer region 90, and a third output terminal 612 of the third wiring 610 is disposed at an edge of the intermediate region 80.

The third input terminal 611 is coupled to the second RF power source 630 through the second matching network 640, and the third output terminal 612 is coupled to a ground through the third capacitor C3. The third wiring 610 receives the RF power at an edge of the outer region 90, and transfers the RF power to an edge of the intermediate region 80.

The third wiring 610 has at least two parallelly coupled conductive wires at an edges of the intermediate region 80 and the outer region 90. The third wiring 610 may have one conductive wire at corners of the intermediate region 80 and the outer region 90 so as to strengthen the induced electric field that has weak electric flux density at the corners of the intermediate region 80 and the outer region 90.

The fourth wiring 620 is formed by rotating the third wiring 610 by about 180 degree with respect to an antenna center point 514. The fourth wiring 620 is formed from an edge of the outer region 90 into an edge of the intermediate region 80. A fourth input terminal 621 of the fourth wiring 620 is disposed at an edge of the outer region 90. The fourth input terminal 621 of the fourth wiring 620 and the third input terminal 611 of the third wiring 610 are arranged substantially diagonally symmetrically with respect to the antenna center point 514. A fourth output terminal 622 of the fourth wiring 620 is disposed at an edge of the intermediate region 80. The fourth output terminal 622 of the fourth wiring 620 and the third output terminal 612 of the third wiring 610 are arranged substantially diagonally symmetrically with respect to the antenna center point 514.

The fourth input terminal 621 of the fourth wiring 620 is coupled to the second RF power source 630 through the second matching network 640, and the fourth output terminal 621 of the fourth wiring 620 is coupled to a ground through a fourth capacitor C4. The effect of the second wiring 520 is substantially the same as that of the first wiring 510. Thus, the RF power is transferred from an edge of the outer region 90 into an edge of the intermediate region 80 via the fourth wiring 620. In addition, the fourth wiring 620 may have at least two parallelly coupled conductive wires at the edges of the intermediate region 80 and the outer region 90. The fourth wiring 620 may have one conductive wire at corners of the intermediate region 80 and the outer region 90 so as to strengthen the induced electric field that has weak electric flux density at the corners of the intermediate region 80 and the outer region 90.

The number of the wirings of the first wiring group 600 may vary depending upon the area of the substrate (workpiece). As illustrated in the embodiment of FIG. 1, when the wavelength of the RF power is λ, the limit length of the wiring through which the RF power is transmitted is λ/4. Thus, the first wiring group 500 may be comprised of two or more than two wirings when the area of the substrate is large, and the first wiring group 500 may be comprised of one wiring when the area of the substrate is narrow.

In addition, the number of the second wiring group 600 may vary depending upon the area of the substrate.

Although FIG. 3 shows that the second RF power source 630 is coupled to the third input terminal 611 of the third wiring 610 and the fourth input terminal 621 of the fourth wiring 620 via the second matching network 640, the third input terminal 611 may be coupled to an RF power source via a matching network, and the fourth input terminal 621 may be coupled to another RF power source via another matching network. In case two different RF power sources are used for the third and fourth input terminals 611 and 621, the frequency of the two different RF power sources may be the same, and the power of the two different RF power sources may be the same.

In addition, a frequency of the first RF power sources 530 may be higher than a frequency of the second RF power sources 540. The frequency of the RF power sources that transmits the RF power from the intermediate region 80 to the internal region 70 may be higher than the frequency of the RF power source that transmits the RF power from the outer region 90 to the intermediate region 80, thereby reducing the plasma loss at the outer region 90.

A sidewall of a chamber in which the plasma is formed is electrically connected to a ground, and the loss of ions and electrons occurs at the sidewall electrically connected to the ground. The amount of the plasma loss at the sidewall is substantially in proportion to the frequency of the RF power applied to the antenna. Namely, the plasma loss at the sidewall is relatively small when the frequency of the RF power is low. Thus, the frequency of the RF power that is transferred from the outer region 90 to the intermediate region 80 is regulated to be relatively low so as to minimize the plasma loss at the outer region 30.

In the example embodiment shown in FIG. 3, the input terminals to which the RF power source is coupled is disposed at edges of the intermediate region 80 and the outer region 90. Since an amplitude of an RF current applied to a wiring decreases according as a distance from a RF power source decreases, the induced electric intensity at the area near to the RF power source is weak. When the input terminal into which the RF power is applied is disposed at a corner, the induced electric intensity near to the corner is weak. Thus, the input terminal into which the RF power is applied is disposed at an edge of the intermediate region 80 and the outer region 90 so that the induced electric intensity near to the corner may not be weaken.

The second wiring group 600 transfers the RF power from the outer region 90 to the intermediate region 80. The phase of the RF power source for providing the RF power to the first wiring group 500 may have the same as the phase of the RF power source for providing the RF power to the second wiring group 600. In the example embodiment shown in FIG. 1, the RF power source for providing the RF power to the first wiring group 500 has have substantially a phase difference of π with respect to the phase of the RF power source for providing the RF power to the second wiring group 600 so that the RF current flowing through the first wiring group 500 has the same phase (or direction) as the phase of the RF current flowing through the second wiring group 600. However, in the example embodiment shown in FIG. 3, the phase of the RF power source for providing the RF power to the first wiring group 500 is the same as the phase of the RF power source for providing the RF power to the second wiring group 600, and the RF current flowing through the first wiring group 500 has the same phase (or direction) as the phase of the RF current flowing through the second wiring group 600. In general, it is difficult to control the amount of the phase difference between two RF powers according as the frequency of the RF power increases. Thus, the RF power sources may be easily controlled by changing the amplitude of the RF power sources while the phases of the RF power sources are not changed.

In the example embodiment shown in FIG. 3, the first wiring group 500 is arranged on the intermediate region 80 and the internal region 70, and the RF power is transferred from the intermediate region 80 to the internal region 70. The second wiring group 600 is arranged on the intermediate region 80 and the outer region 90, and the RF power is transferred from the outer region 90 to the intermediate region 80. In above described arrangement of the wiring groups 500 and 600, there is an advantage that the phase of the RF power source that provides the RF power to the first wiring group 500 is the same as the phase of the RF power source that provides the RF power to the second wiring group 600.

An RF power source is coupled to edges of the outer region 90, or at least two parallelly coupled conductive wires is disposed at edges of the outer region 90. One conductive wire is disposed in the internal region 70. Therefore, uniform induced electric flux density is formed throughout the overall regions (internal, intermediate and outer regions) of the antenna, and uniform plasma flux density may be obtained based on the uniform induced electric flux density. In addition, the plasma loss at the outer region 30 may be minimized due to the relatively low frequency of the RF power that is transferred through the outer region 90.

According to the antenna of a plasma processing apparatus, the antenna includes first and second wiring groups that are electrically independent each other, and the RF current flowing through the first wiring group has the same phase (or direction) as the phase of the RF current flowing through the second wiring group.

In addition, the first wiring group receives the RF power to transfers the received RF power to the antenna center point. Thus, the electric flux density in the outer region, where relatively weak electric flux density is induced, is strengthened, and uniform plasma density may be obtained. Especially, the frequency of the RF power transmitted to the first wiring group is different from the frequency of the RF power transmitted to the second wiring group. The frequency of the RF power transmitting through the outer region is relatively low compared with the frequency of the RF power transmitting through the internal region so as to reduce the plasma loss at the sidewall of the chamber. Therefore, uniform plasma flux density may be obtained in the plasma processing of a large substrate.

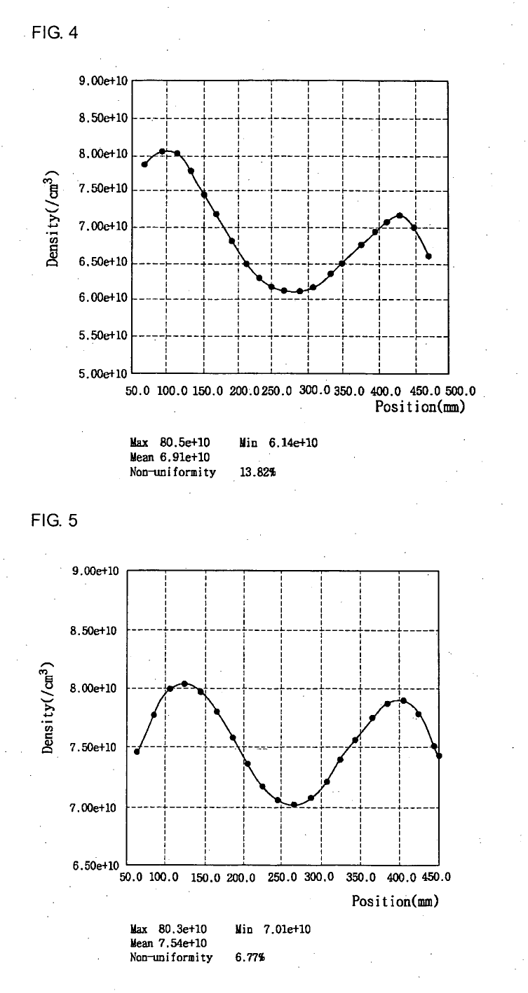

FIGS. 4 and 5 show that the distribution of the plasma density of the antenna of the plasma processing apparatus of the present invention is enhanced compared with that of the conventional antenna of the plasma processing apparatus.

FIG. 4 is a graph showing plasma density distribution under a conventional antenna when the RF power source applies the RF power to the internal region, and FIG. 5 is a graph showing a plasma density distribution under an antenna according to an exemplary embodiment of the present invention when the RF power source applies the RF power to the intermediate region.

In the conventional antenna in which the RF power is applied to the internal region, the plasma density is in a range from a maximum value of about 8.05×e¹⁰/cm³ to a minimum value of about 6.14×e¹⁰/cm³. Thus, the non-uniformity of the plasma density is about 13.82%. However, in the antenna according to an exemplary embodiment of the present invention in which the RF power is applied to the intermediate region to be transmitted to the internal region, the plasma density is in a range from a maximum value of about 8.03×e¹⁰/cm³ to a minimum value of about 7.01×e¹⁰/cm³. Thus, the non-uniformity of the plasma density may be enhanced, and the average plasma density is increased from 6.91×e¹⁰/cm³ to 7.54×e¹⁰/cm³.

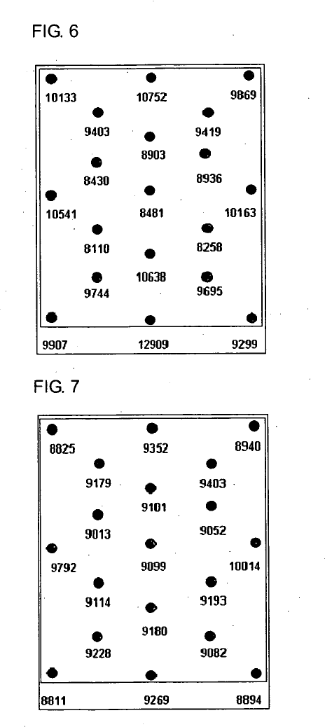

FIGS. 6 and 7 show that the etching rate of the plasma density of the antenna of the plasma processing apparatus of the present invention is enhanced compared with that of the conventional antenna of the plasma processing apparatus.

In FIGS. 6 and 7, the etching process is performed on the same kind of substrate under the same process condition, 8 Kilowatt of RF power source and 5 Kilowatt of bias voltage source is used, 1000 sccm (Standard Cubic Centimeter per Minute) of oxygen and the pressure is 10 mTorr is used.

FIG. 6 shows etching rate under a conventional antenna when the RF power source applies the RF power to the internal region.

Referring to FIG. 6, the etching rate is in a range from a maximum value of about 12909 Å/min to a minimum value of about 8110 Å/min. Namely, the difference of the etching rate throughout the internal region and the outer region is about 4799 Å/min.

FIG. 7 shows etching rate under an antenna according to an exemplary embodiment of the present invention when the RF power source applies the RF power to the intermediate region.

Referring to FIG. 7, the etching rate is in a range from a maximum value of about 10014 Å/min to a minimum value of about 8811 Å/min. Namely, the difference of the etching rate throughout the overall region is about 1203 Å/min, and thus the difference of the etching rate was remarkably enhanced.

While the example embodiments of the present invention and their advantages have been described in detail, it should be understood that various changes, substitutions and alterations may be made herein without departing from the scope of the invention.

What is claimed is:

1. An antenna of a plasma processing apparatus, the antenna comprising:
a first wiring group formed on an internal region and an intermediate region, the first wiring group transferring a power of a first RF (radio frequency) power source from the intermediate region to the internal region; and
a second wiring group formed on the intermediate region and an outer region, the second wiring group transferring a power of a second RF (radio frequency) power source from the intermediate region to the outer region.

2. The antenna of the plasma processing apparatus of claim 1, wherein the first wiring group includes:
a first wiring formed from the intermediate region into the internal region so that the first wiring may have a first square spiral configuration; and
a second wiring formed from the intermediate region into the internal region so that the second wiring may have a second square spiral configuration,
and wherein the first and second wirings are arranged substantially diagonally symmetrically with respect to an antenna center point.

3. The antenna of the plasma processing apparatus of claim 2, wherein the first and second wirings receive the power of the first RF power source via first and second input terminals, respectively, disposed in the intermediate region, and transfers the power of the first RF power source toward first and second output terminals, respectively, disposed in the internal region.

4. The antenna of the plasma processing apparatus of claim 2, wherein the first and second wirings respectively have at least two parallelly coupled conductive wires in the intermediate region, and respectively have a conductive wire in the internal region.

5. The antenna of the plasma processing apparatus of claim 1, wherein the second wiring group includes a third wiring formed from the intermediate region into the outer region, and the third wiring receives the power of the second RF power source via a third input terminal disposed at an edge of the intermediate region and transfers the power of the second RF power source toward a third output terminal disposed at an edge of the outer region.

6. The antenna of the plasma processing apparatus of claim 5, wherein the third wiring has at least two parallelly coupled conductive wires at the edge of the intermediate region or at an edge of the outer region, and have a conductive wire at a corner of the outer region.

7. The antenna of the plasma processing apparatus of claim 6, wherein the second wiring group further includes fourth, fifth and sixth wirings, and the fourth, fifth and sixth wirings are formed by rotating the third wiring by about 90 degree, about 180 degree and about 270 degree with respect to an antenna center point.

8. The antenna of the plasma processing apparatus of claim 1, wherein a frequency of the second RF power source is lower than a frequency of the first RF power source such that a plasma loss at the outer region is reduced.

9. An antenna of a plasma processing apparatus, the antenna comprising:
a first wiring group formed on an internal region and an intermediate region, the first wiring group transferring a power of a first RF (radio frequency) power source from the intermediate region to the internal region; and
a second wiring group formed on the intermediate region and an outer region, the second wiring group transferring a power of a second RF (radio frequency) power source from the outer region to the intermediate region.

10. The antenna of the plasma processing apparatus of claim 9, wherein the first wiring group includes a first wiring, and the first wiring receives the power of the first RF power source via an input terminal disposed at an edge of the intermediate region and transfers the power of the first RF power source toward the internal region.

11. The antenna of the plasma processing apparatus of claim 10, wherein the first wiring has at least two parallelly coupled conductive wires in the intermediate region and has a conductive wire in the internal region.

12. The antenna of the plasma processing apparatus of claim 11, wherein the first wiring has a conductive wire at corners of the intermediate region.

13. The antenna of the plasma processing apparatus of claim 12, wherein the first wiring group further includes a second wiring, and the second wiring has the same shape as that of the first wiring and is formed by rotating the first wiring by about 90 degree with respect to an antenna center point.

14. The antenna of the plasma processing apparatus of claim 9, wherein the second wiring group includes a third wiring formed from the outer region into the intermediate region, and the third wiring receives the power of the second RF power source via an input terminal disposed at an edge of the outer region and transfers the power of the second RF power source toward an output terminal disposed at an edge of the intermediate region.

15. The antenna of the plasma processing apparatus of claim 14, wherein the third wiring has at least two parallelly coupled conductive wires at edges of the intermediate region or at edges of the outer region, and have a conductive wire at corners of the intermediate region or at corners of the outer region.

16. The antenna of the plasma processing apparatus of claim 15, wherein the second wiring group further includes a fourth wiring, and the fourth wiring has the same shape as that of the third wiring and is formed by rotating the third wiring by about 180 degree with respect to an antenna center point.

17. The antenna of the plasma processing apparatus of claim 9, wherein a frequency of the second RF power source is lower than a frequency of the first RF power source such that a plasma loss at the outer region is reduced.

18. An antenna of a plasma processing apparatus, the antenna comprising:
a first wiring group formed from on an internal region and an intermediate region, the first wiring group receiving a power of a first RF (radio frequency) power source; and
a second wiring group formed on the intermediate region and an outer region, the second wiring group receiving a power of a second RF (radio frequency) power source different from the first RF power source.

19. The antenna of the plasma processing apparatus of claim 18, wherein the first wiring group generates a first induced electric field in response to a first RF (radio frequency) current, the second wiring group generates a second induced electric field in response to a second RF (radio frequency) current, and directions of the first and the second RF currents are the same each other.

20. The antenna of the plasma processing apparatus of claim 19, wherein a frequency of the second RF power source is lower than a frequency of the first RF power source.

21. The antenna of the plasma processing apparatus of claim 18, wherein the first wiring group includes at least one wiring, and the at least one wiring receives the power of the first RF power source at the intermediate region and transfers the received power of the first RF power source toward the internal region.

22. The antenna of the plasma processing apparatus of claim 18, wherein the second wiring group includes at least one wiring, and the at least one wiring receives the power of the second RF power source at an edge of the intermediate region or at an edge of the outer region.
